(19) United States
(12) Patent Application Publication
(10) Pub. No.: US 2026/0206496 A1
(43) Pub. Date: Jul. 16, 2026

(54) SURFACE TREATMENT FOR SUPERCONDUCTING CIRCUIT FABRICATION

(71) Applicant: Amazon Technologies, Inc., Seattle, WA (US)

(72) Inventors: Neha Bharat MAHULI, Pasadena, CA (US); Jefferson Earl ROSE, Hawthorne, CA (US); Ignace JARRIGE, Arcadia, CA (US); Omar REYNA, Pasadena, CA (US); Joaquin MINGUZZI ARANIS, Pasadena, CA (US); David John PERELLO, Temple City, CA (US); Jiansong GAO, Arcadia, CA (US); William Maxwell JONES, Arcadia, CA (US); Gregory Scott MACCABE, Pasadena, CA (US); Guillaume MARCAUD, Los Angeles, CA (US); Victor LY, West Covina, CA (US); Matthew MATHENY, Diamond Bar, CA (US); Loren SWENSON, La Canada Flintridge, CA (US); Matthew Sullivan HUNT, Los Angeles, CA (US); Rassul KARABALIN, Huntington Beach, CA (US); Oskar Jon PAINTER, Sierra Madre, CA (US); Sandra Milena DIEZ PINZON, Altadena, CA (US)

(21) Appl. No.: 19/095,694

(22) Filed: Mar. 31, 2025

Related U.S. Application Data
(60) Provisional application No. 63/746,149, filed on Jan. 16, 2025.

(51) Int. Cl. H10N 60/01; H10N 60/12

(52) U.S. Cl. CPC H10N 60/0912; H10N 60/12

(57) ABSTRACT

A surface treatment for use in fabrication of superconductor devices is disclosed. The surface treatment may include an isotropic chemical etch that removes native surface oxide layers and other contaminants, followed by a conformal deposition of a thin dielectric film. The surface treatment may be performed one or more times, at any of several stages in the fabrication of a superconductor device. Applying the surface treatment to a substrate prior to junction formation may provide improved within-wafer uniformity and wafer-to-wafer reproducibility of the resistance targeting. Applying the surface treatment on top of finished junctions and ground plane materials may provide reduced microwave losses, in addition to the increased within-wafer uniformity and wafer-to-wafer reproducibility of the junction resistance.

### CROSS REFERENCE TO RELATED APPLICATIONS

This application claims the benefit of priority to U.S. Provisional Patent Application No. 63/746,149, entitled, “Surface Treatment for Superconducting Circuit Fabrication”, filed on Jan. 16, 2025, the disclosure of which is hereby incorporated herein in its entirety.

### BACKGROUND

Superconducting circuits may include superconducting circuit elements, such as Josephson junctions, qubits, and airbridges.

### BRIEF DESCRIPTION OF THE DRAWINGS

Certain features of the subject technology are set forth in the appended claims. However, for the purpose of explanation, several embodiments of the subject technology are set forth in the following figures. However, for purposes of explanation, several aspects of the subject technology are depicted in the following figures.

FIG. 1 is a block diagram depicting a system including a quantum computer according to aspects of the subject technology.

FIG. 2 is a block diagram illustrating a quantum computing system having a quantum processor according to aspects of the subject technology.

FIG. 3 illustrates a cross-sectional view of a portion of a superconductor device according to aspects of the subject technology.

FIG. 4 illustrates a cross-sectional view of a portion of another superconductor device according to aspects of the subject technology.

FIGS. 5A, 5B, 5C, 5D, 5E, 5F, 5G, 5H, 5I, 5J, 5K and 5L illustrate various stages of fabrication of superconductor devices according to aspects of the subject technology.

FIG. 6 is a flowchart of illustrative operations that may be performed for fabrication of a superconductor device according to aspects of the subject technology.

FIG. 7 is a flowchart of illustrative operations that may be performed for superconducting circuit fabrication using post-singulation surface treatment according to aspects of the subject technology.

FIG. 8 illustrates an example electronic device in which aspects of the subject technology may be used, in accordance with one or more embodiments of the subject technology.

### DETAILED DESCRIPTION

The description set forth below describes various configurations of the subject technology and is not intended to represent the only configurations in which the subject technology may be practiced. The appended drawings are incorporated herein and constitute a part of the description. The description includes specific details for the purpose of providing an understanding of the subject technology. However, the subject technology is not limited to the specific details set forth herein and may be practiced using one or more other embodiments of the subject technology. In one or more embodiments of the subject technology, structures and components are shown in block diagram form in order to avoid obscuring the concepts of the subject technology.

The present description relates generally to quantum computing, and more particularly to, for example, surface treatments for superconducting circuit fabrication.

Obstacles facing the realization of commercial fault tolerant quantum computing can be related to challenges in the fabrication of superconducting circuits, such as superconducting quantum circuits. Among these obstacles are (i) improving wafer-to-wafer reproducibility, (ii) increasing within-wafer uniformity of the frequency resistance targeting of the junctions, and (iii) reducing microwave losses.

Aspects of the subject technology relate to a surface treatment process that is capable of addressing some or all of these challenges. As discussed in further detail hereinafter, the disclosed surface treatment may include a surface processing (e.g., isotropic chemical etching) that removes native surface oxide layers and other contaminants, followed by conformal deposition of a thin dielectric film. By applying the surface treatment to a substrate prior to, for example, junction formation on the substrate, an improved within-wafer uniformity and wafer-to-wafer reproducibility of the resistance targeting can be achieved. In some examples, when the surface treatment is applied on top of finished junctions and a ground plane, reduced microwave losses can be achieved, in addition to the increased within-wafer uniformity and wafer-to-wafer reproducibility of the junction resistance.

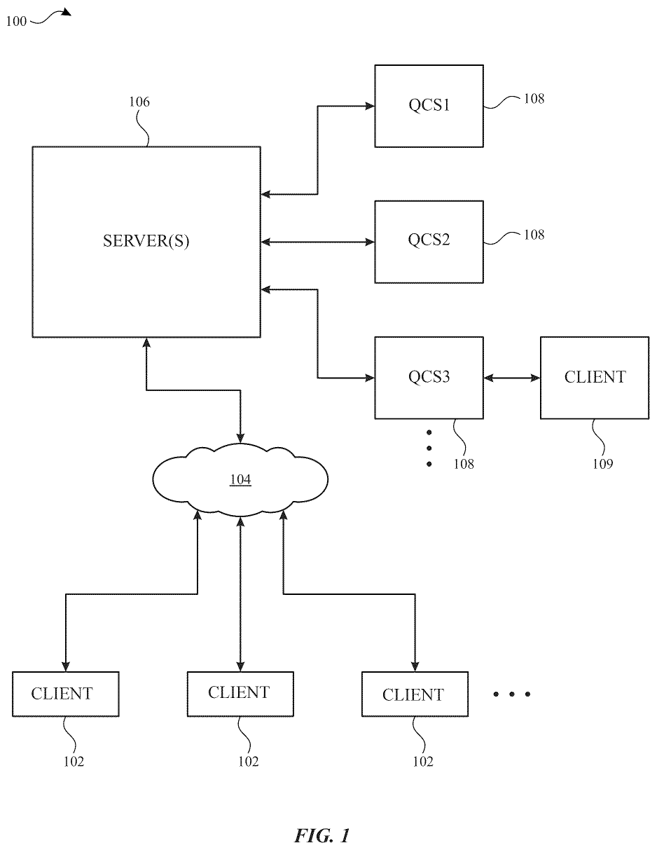

FIG. 1 is a block diagram depicting a system that may incorporate a quantum computer according to aspects of the subject technology. Not all of the depicted components may be required, however, and one or more implementations may include additional components not shown in the figure. Variations in the arrangement and type of the components may be made without departing from the spirit or scope of the claims as set forth herein. Depicted or described connections and couplings between components are not limited to direct connections or direct couplings and may be implemented with one or more intervening components unless expressly stated otherwise.

As depicted in FIG. 1, a system 100 may include one or more client devices 102, one or more servers 106, and/or one or more quantum computing systems 108. As shown, the client devices 102 may be communicatively coupled to the server(s) 106 via a network 104. For example, the network 104 may represent one or more local area networks (LANs) and/or one or more wider area networks, such as the Internet. In one or more implementations, the server(s) 106 may implement one or more web services that can be accessed by one or more of the client devices 102 via the network 104. In one or more implementations, the web services provided by the servers 106 may include quantum computing services. For example, the server(s) 106 may facilitate access to one or more of the quantum computing systems 108, such as from a client device 102.

In the example of FIG. 1, the quantum computing systems 108 include a first quantum computing system, QCS1, a second quantum computing system, QCS2, and a third quantum computing system, QCS3. However, it is appreciated that this is merely illustrative, and the system 100 may include more or fewer than three quantum computing systems in other implementations. In various examples, the multiple quantum computing systems QCS1, QCS2, and QCS3 may represent multiple instances of a same or similar type of quantum computing system, or implementations of multiple different types of quantum computing systems. For example, different types of quantum computing systems may implement different types of qubit architectures, as will be discussed in further detail hereinafter.

Although FIG. 1 illustrates an example in which one or more quantum computing systems can be accessed by a web services provider, in one or more implementations, one or more of the quantum computing systems 108 may also, or alternatively, be accessible directly (e.g., locally at the quantum computing system). For example, FIG. 1 also illustrates how a quantum computing system 108 may be accessed directly from a client interface 109 that is directly communicatively coupled to the quantum computing system 108. For example, the client interface 109 may include one or more input/output components, such as keyboards, display screens, touch interfaces, etc. that can be operated by a user to control an associated quantum computing system 108. In one or more implementations, the client interface 109 and the quantum computing system 108 can be integrated into a common package (e.g., as a standalone quantum computer).

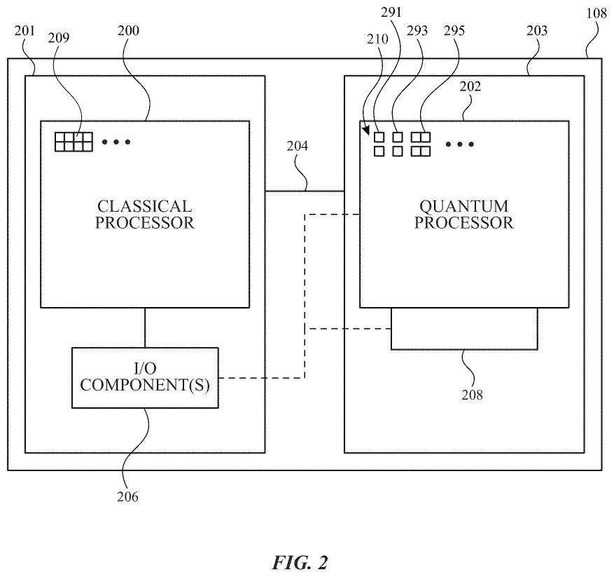

FIG. 2 is a block diagram depicting an example of a quantum computing system according to aspects of the subject technology. In the example of FIG. 2, the quantum computing system 108 includes both classical computer 201 and a quantum computer 203. As shown, the classical computer 201 may include one or more classical processors, such as a classical processor 200. As shown, the quantum computer 203 may include one or more quantum processors, such as a quantum processor 202. In this example, the classical computer 201 is coupled to the quantum computer 203 via an interface 204 over which control signals can be sent from the classical processor 200 to the quantum processor 202. In this example, the quantum computing system 108 may include one or more input/output components 206, such as keyboards, display screens, touch interfaces, etc. that can be operated by a user to control the classical processor 200, such as for generating commands and/or associated control signals for the quantum processor 202.

In the example of FIG. 2, the quantum computing system 108 may include drive circuitry 208 for the quantum processor 202. For example, the drive circuitry 208 may include one or more electromagnetic pulse generators (e.g., microwave pulse generators, such as one more lasers and/or other light sources), and/or corresponding electrical and/or optical pathways for guiding electromagnetic pulses to one or more qubits of the quantum processor, for controlling operation of the quantum processor 202. In the example of FIG. 2, the drive circuitry 208 is depicted as being arranged along an edge of the quantum processor 202. However, this is merely illustrative, and, in various implementations, the drive circuitry 208 may be otherwise arranged with respect to, and/or integrated within, the classical computer 201 or the quantum processor 202.

As illustrated in FIG. 2, the classical processor 200 may include transistors 209 (e.g., thousands, millions, billions, or trillions of transistors 209). For example, the transistors 209 may be formed in a silicon substrate using one or more semiconductor processing operations (e.g., etching, lithography, etc.). The classical processor 200 may include classical logic gates (e.g., thousands, millions, billions, or trillions of classical logic gates), each formed by combinations of one or more of the transistors 209 and/or other circuit elements formed in the silicon substrate.

Although the example of FIG. 2 depicts a quantum computing system 108 that includes a classical computer 201 with a classical processor 200, it is appreciated that, in one or more implementations, a quantum computing system 108 may be provided without a classical computer 201. For example, as indicated by the dashed lines in FIG. 2, in one or more implementations, input/output (I/O) components 206 may be directly coupled to the quantum processor and/or the drive circuitry 208 for controlling operation of the quantum processor 202 without involvement of a classical processor 200.

As shown, the quantum processor 202 may include various quantum circuit elements 210. As examples, the quantum circuit elements 210 may include one or more junctions such as Josephson junctions, one or more qubits 291 (e.g., qubits incorporating Josephson junctions), one or more resonators 293, one or more transmission lines, one or more vias (e.g., through-silicon vias (TSVs) or other through-substrate vias), one or more airbridges 295, a ground plane, readout circuitry and/or other circuitry for a quantum computing circuit and/or a quantum computing chip including one or more quantum computing circuits. For example, the quantum circuit elements 210 may include tens, hundreds, thousands, millions, billions, or trillions of Josephson junctions in one or more implementations. For example, the quantum circuit elements 210 may include tens, hundreds, thousands, millions, billions, or trillions of qubits 291 in one or more implementations. The quantum circuit elements 210 may also, or alternatively, include tens, hundreds, thousands, millions, billions, or trillions of resonators 293 in one or more implementations. In some examples, some or all of the qubits 291 may each represent a single physical qubit, or may represent a logical qubit, which may be formed from one, two, or more than two physical qubits.

Qubits 291 of the quantum circuit elements 210 may be used, by the quantum processor 202, individually and/or in various combinations, for storage of information, and/or for operating a quantum computing circuit (e.g., superconducting circuit including the qubits and/or one or more other quantum circuit elements, such as resonators, feedlines, readout circuitry, etc.). In various implementations, qubits 291 of the quantum circuit elements 210 may be implemented as trapped-ion qubits (e.g., including trapped ionized ytterbium atoms), superconducting qubits (e.g., transmons), Rydberg atom qubits, tunable superconducting qubits, quantum dot qubits, topological qubits, photonic qubits, Nuclear Magnetic Resonance (NMR) qubits, diamond nitrogen-vacancy (NV) center qubits, and/or any other suitable qubit architectures and/or quantum-scale anharmonic systems. In some implementations, quantum circuit elements 210 may be implemented on a substrate (e.g., a silicon, gallium arsenide, graphene, sapphire, aluminum nitride, and silicon carbide, or other substrate). For example, some qubits 291 may be implemented using a superconducting loop that includes a Josephson junction on a silicon substrate. For example, the quantum circuit element 210 may be superconducting circuit elements of a superconducting circuit, which may be implemented for quantum computing.

In quantum computing, bits can be encoded as quantum states, rather than distinct zeros and ones. The use of quantum effects, such as entanglement and interference, can provide significant advantages, relative to classical processors, in certain computation tasks. Some implementations of quantum computing circuitry use superconducting circuits. For example, a qubit 291 may be formed from a superconducting circuit that includes one or more Josephson junctions (JJs) (e.g., a JJ shunted by a capacitor and coupled to a linear resonator), a configuration which is referred to as a transmon qubit.

In order to achieve a desired transmon frequency, each JJ is designed with a specific size to determine the junction energy (Ej). In theory, Ej is determined by the junction area, the insulating layer thickness, and the superconductor properties. It is extremely difficult to form the junction close to the targeted Ej. The factors that affect the final junction energy are a subject of active research. They include, but are not limited to, superconductor grain size, surface properties, substrate condition, prior process history, fabrication process parameters, subsequent processing conditions (e.g., aging), time spent in ambient or other conditions, and deposition uncertainties, among others. The magnitudes of Ej variation across a wafer and between wafers can often render devices unusable.

Transmon coherence is characterized by the relaxation time T₁ and dephasing time T₂, which are typically limited by microwave losses from amorphous disordered dielectrics and/or fabrication contaminants located at the surface of the structural materials, also known as two-level system (TLS) loss. While these dielectrics should be eliminated, or at least reduced, in transmon fabrication to improve coherence times, most commonly used materials for quantum computing hardware tend to form native oxide films in ambient environments.

In order to address these challenges, a surface treatment (e.g., a surface engineering process) is disclosed herein that uses a combination of removal (e.g., using isotropic chemical etching) of any undesired disordered dielectric layers from the device surfaces (e.g., native oxide layers), followed by a conformal deposition of a fresh, high-quality, and well-controlled dielectric coating. The surface treatment can be applied to a substrate prior to fabrication of superconducting circuit elements (e.g., quantum circuit elements 210, including Josephson junctions, resonators 293, airbridges 295, etc.), and/or after their formation. The surface treatment may be performed at one or more stages of fabrication of a superconducting device (e.g., a quantum processor), without breaking vacuum between the oxide-removal and the dielectric-deposition processes.

In implementations in which the disclosed surface treatment is applied to a substrate prior to junction formation, a more favorable and consistent processing regime may be created for junction fabrication, which leads to superior wafer-to-wafer reproducibility of the junction resistance targeting, which can be used as proxy for transmon frequency targeting. In implementations in which the surface treatment is also, or alternatively, applied after junction formation, unwanted loss channels from disordered dielectric layers may be curtailed, thus resulting in increased T₁ and T₂ times. In addition, applying the surface treatment after junction formation reduces the sensitivity of the junction resistance to subsequent process steps, resulting in a better within-wafer uniformity as well as superior wafer-to-wafer reproducibility.

Various implementations of superconducting circuits (e.g., including qubits) formed using the disclosed surface treatment demonstrate (i) a factor of greater than four improvement in wafer-to-wafer reproducibility of the frequency, (ii) a factor of approximately two increase in wafer uniformity of the frequency, and (iii) up to 175% increase in T₁. These improvements may help to realize commercial fault tolerant quantum computers, providing direct improvements in performance and scalability. The disclosed surface treatment and its benefits are directly applicable to superconducting-based circuit implementations, such as transmon qubits.

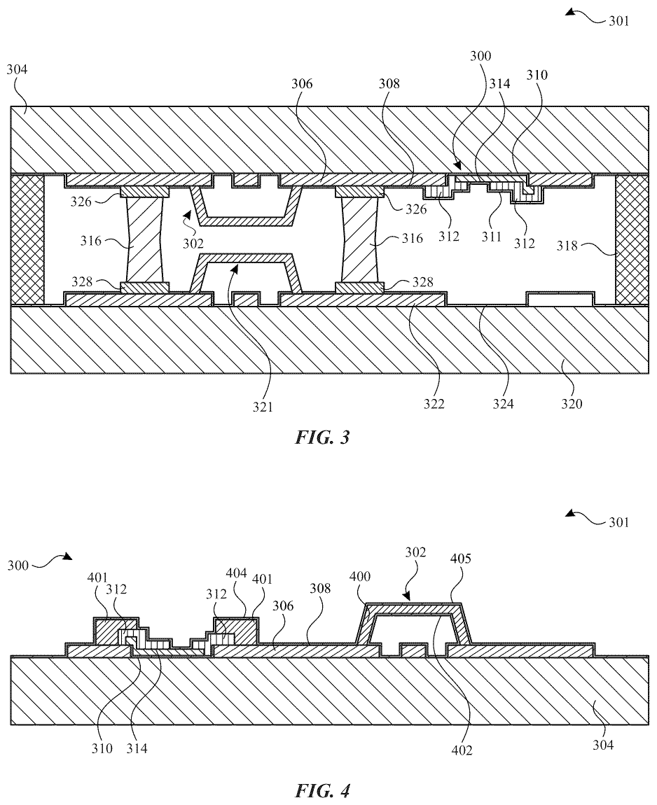

FIG. 3 illustrates a cross-sectional side view of a portion of a superconductor device 301 (e.g., which may be an implementation of the quantum processor 202, in which one or more materials are superconducting, such as when the device is sufficiently cooled) in accordance with one or more implementations. In the example of FIG. 3, the superconductor device 301 is implemented using a three-dimensional (3D), or flip-chip, architecture. The superconductor device 301 of FIG. 3 may be formed using one or more applications of the surface treatment discussed in further detail hereinafter, and includes various observable features resulting from the performance of the surface treatment(s).

In the example of FIG. 3, the superconductor device 301 includes a substrate 304, a Josephson junction 300 on the substrate 304, and a dielectric layer 310 interposed between a portion of the Josephson junction 300 and the substrate 304. For example, the dielectric layer 310 may have been formed as part of the surface treatment disclosed herein, following removal of a native oxide layer from the substrate 304 and prior to formation of the Josephson junction 300. For example, the superconductor device 301 may be free of native oxide layers between the substrate 304 and the Josephson junction 300 (e.g., due to the removal of one or more native oxide layers from the surface of the substrate prior to deposition of the dielectric layer 310, without breaking vacuum between the removal and deposition processes). As examples, the dielectric layer 310 may be formed from alumina (e.g., an aluminum oxide, such as Al₂O₃), aluminum nitride (AlN), silicon nitride (e.g., Si₃N₄), or magnesium oxide (MgO).

As shown in FIG. 3, the Josephson junction 300 may include a pair of superconducting elements 312 (e.g., electrodes formed from a superconducting metal, such as aluminum, niobium, tantalum, titanium nitride, lead, magnesium diboride, yttrium and/or other superconducting materials), and a non-superconducting material 314 disposed between (e.g., and separating) the pair of superconducting elements 312. For example, the non-superconducting material 314 may be formed from an insulating material (e.g., aluminum oxide, magnesium oxide, and/or another insulator) and/or other non-superconducting materials.

As shown in FIG. 3, the portion of the Josephson junction 300 that is in contact with the dielectric layer 310 may include a portion of the non-superconducting material 314. As shown, the portion of the Josephson junction 300 that is in contact with the dielectric layer 310 may also include a portion of one of (or both of) the superconducting elements 312.

As shown in FIG. 3, the superconductor device 301 may also include a ground plane layer 306 on the substrate 304. As shown, a dielectric layer 308 may extend over the ground plane layer 306. In various implementations (e.g., depending on the process steps for forming the superconductor device 301, including when and/or how many times the disclosed surface treatment was applied), the dielectric layer 308 may be a portion of the dielectric layer 310 and/or a portion of another dielectric layer, such as a dielectric layer 311 that is formed over the Josephson junction 300. Each of the dielectric layers 308 and 311 may be formed as part of the disclosed surface treatment, following (e.g., without breaking vacuum), removal of a native oxide layer. For example, the ground plane layer 306 may be free of native oxide layers between the ground plane layer 306 and the dielectric layer 308 (e.g., due to removal of one or more native oxide layers from the ground plane layer and/or exposed portions of the substrate 304, prior to deposition of the dielectric layer 308). In the example of FIG. 3, a portion of each of the pair of superconducting elements 312 is in contact with the ground plane layer 306 (e.g., to allow control of the Josephson junction 300 via transmission of signals to the superconducting elements 312 via the ground plane layer 306).

As shown in the example of FIG. 3, the superconductor device 301 may include one or more airbridges, such as airbridge 302, on the substrate 304. In the example of FIG. 3, gaps in the dielectric layer 308 allow contact between the airbridge 302 and the ground plane layer 306. In the example of FIG. 3, the superconductor device 301 also includes structures and components for implementing the 3D architecture of this implementation. These structures and components include bond stops 318, bumps 316 (e.g., indium bumps), and under-bump metallizations (UBMs) 326. As shown, gaps in the dielectric layer 308 allow the UBMs 326 to contact the ground plane layer 306.

In the example of FIG. 3, the superconductor device 301 includes another substrate 320 (e.g., a separate routing substrate) that may carry resonators (e.g., resonators 293 of FIG. 2) and/or routing lines in a ground plane layer 322. The ground plane layer 322 may also be impacted by lossy native oxides if present. Accordingly, the disclosed surface treatment may also be applied to the substrate 320. For example, as shown, a dielectric layer 324 may be formed on the substrate 320 and the ground plane layer 322. The substrate 320 and/or the ground plane layer 322 may be free of native oxide layers (e.g., due to removal of one or more native oxide layers therefrom prior to deposition of the dielectric layer 324, without breaking vacuum between the removal and deposition processes). As shown, gaps in the dielectric layer 324 may allow contact between an airbridge 321 and the ground plane layer, and/or between under-bump metallizations 328 (e.g., which couple to the bumps 316) and the ground plane layer 322.

In various implementations, the Josephson junction 300 and/or the airbridge 302 may be implementations of the quantum circuit elements 210 of FIG. 2 (e.g., the Josephson junction may form a part of a qubit 291 and/or the airbridge 302 may be an implementation of an airbridge 295). It is also appreciated that others of the quantum circuit elements 210 of FIG. 2, including one or more resonators 293, may be formed on the substrate 304, and that the surface treatment disclosed herein may be applied to remove native oxide layers from the resonators 293 and to deposit a dielectric layer (e.g., a portion of the dielectric layer 308, the dielectric layer 310, and/or the dielectric layer 311) on the resonator. In one or more implementations, one or more resonators 293 may be formed from one or more patterned portions of the ground plane layer 306. Accordingly, in one or more implementations, the superconductor device 301 may include a resonator 293 on the substrate 304, and the resonator 293 may be free of native oxide layers thereon. A portion of the dielectric layer 308, the dielectric layer 310, and/or the dielectric layer 311 may extend over a surface of at least a portion of the resonator 293. As shown, a portion of the dielectric layer 308, the dielectric layer 310, and/or the dielectric layer 311 may be formed on a sidewall of the bond stops 318.

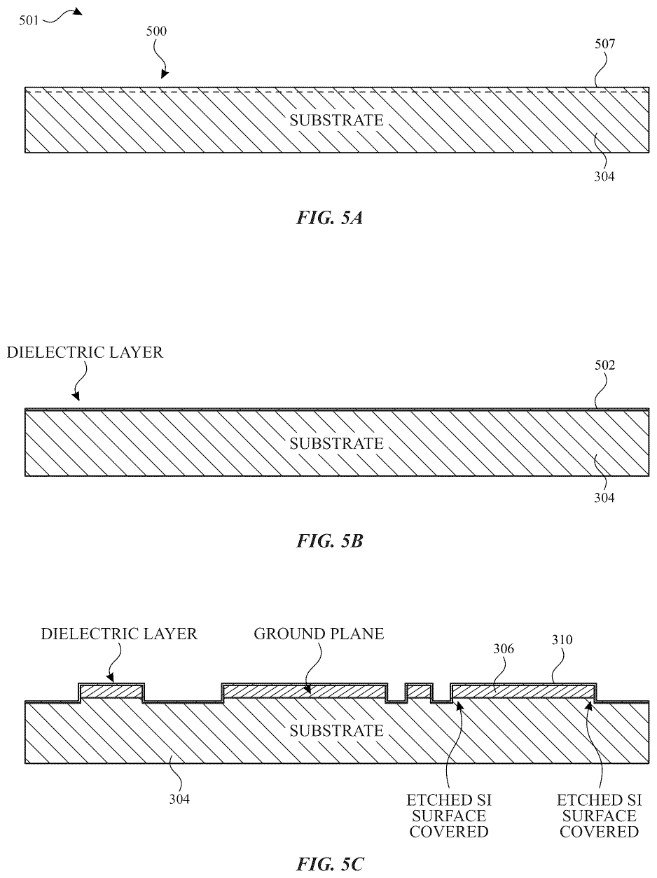

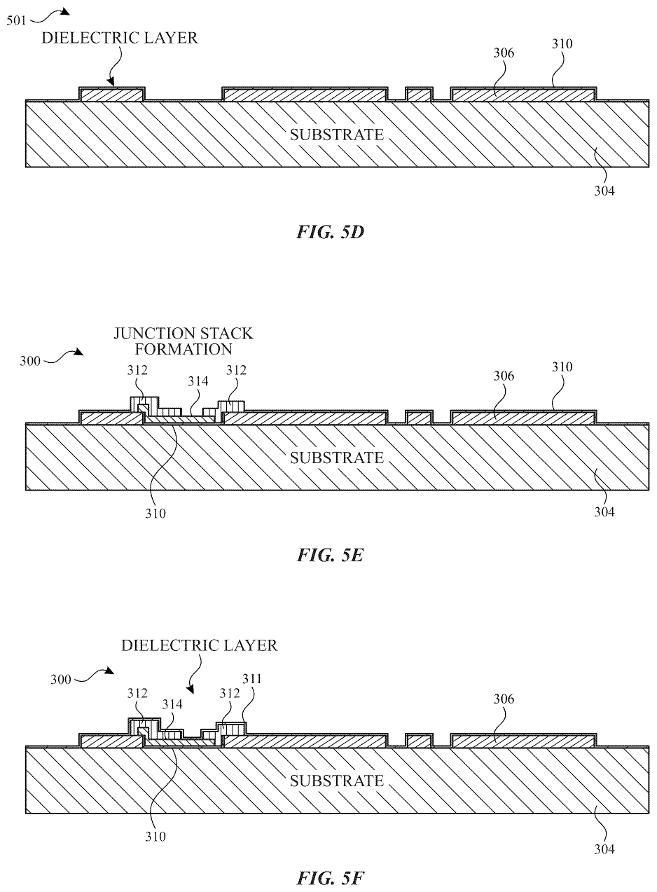

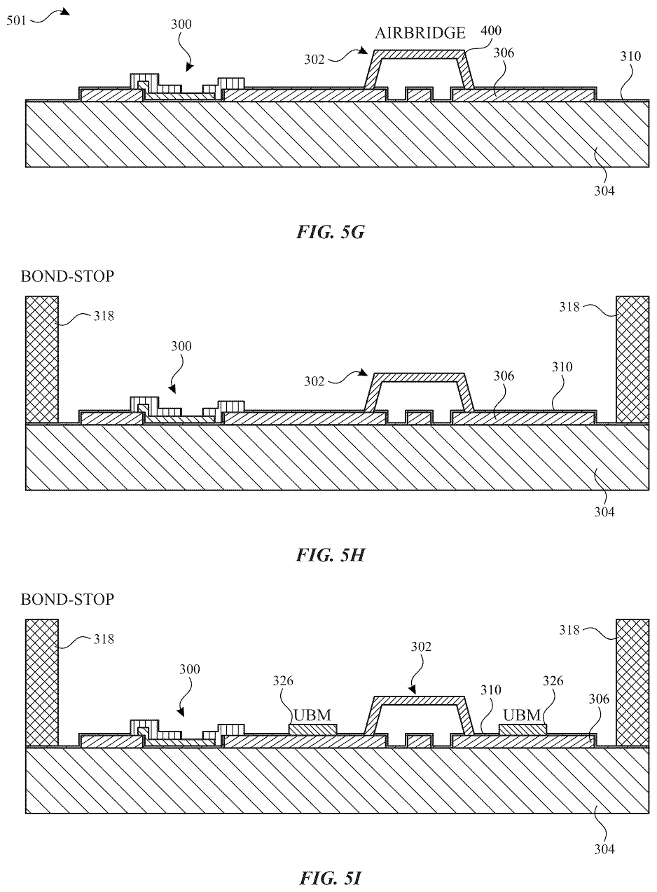

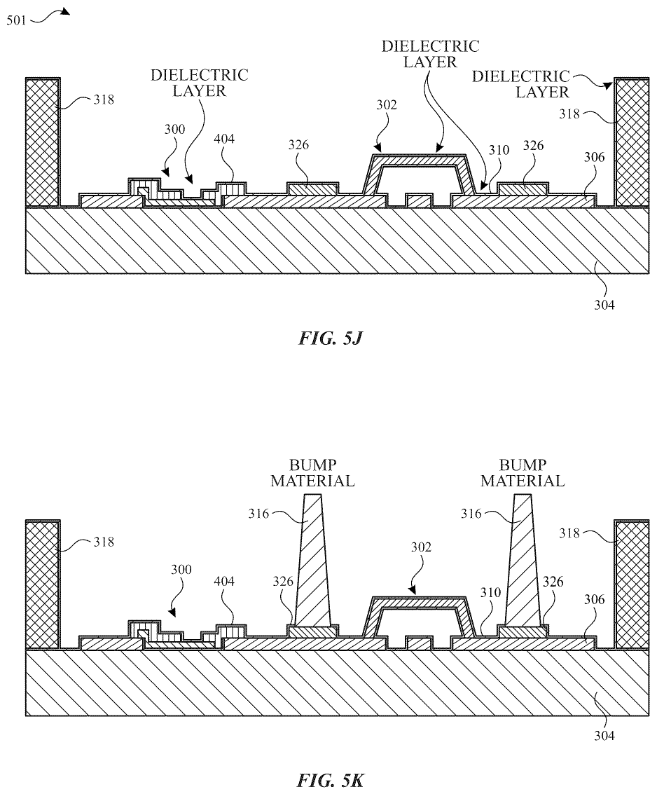

A discussed in further detail hereinafter (see, e.g., FIGS. 5A-5L), the superconductor device 301 of FIG. 3 may be formed by forming the ground plane layer 306, the Josephson junction 300, the airbridge 302, the bond stops 318, the UBMs 326, and first portions of the bumps 316 on the substrate 304; separately forming the ground plane layer 322, the dielectric layer 324, the UBMs 328, and second portions of the bumps 316 on the substrate 320; flipping the substrate 304; and bonding the first portions of the bumps 316 to the second portions of the bumps 316. Although a single Josephson junction 300, a single airbridge 302, two bond stops 318 and two bumps 316 are shown on the substrate 304, it is appreciated that the example of FIG. 3 shows only a portion of the superconductor device 301, and, in various implementations, any number of Josephson junctions, airbridges, bond stops, UMBs, and bumps, resonators, other quantum circuit elements 210, and/or other suitable structures and/or components of a superconducting device may be formed on the substrate 304.

In the example of FIG. 3, the airbridge 302 and the airbridge 321 are depicted as being free of the dielectric layers 310, 311, 308, and/or 324. However, it is appreciated that, in one or more implementations, the surface treatment described herein can be applied to either or both of the surfaces of the airbridge 302, the airbridge 321, and/or other airbridges on the substrate 304, and/or the substrate 320. Thus, either or both of the surfaces of the airbridge 302, the airbridge 321, and/or other airbridges on the substrate 304, and/or the substrate 320 may have a dielectric layer formed thereon. For example, in some implementations, the dielectric layer 308 and/or another dielectric layer may extend over an outer (e.g., top) surface of the airbridge 302. In some implementations, the dielectric layer 324 and/or another dielectric layer may extend over an outer (e.g., top) surface the airbridge 321. In some implementations, a dielectric layer may be formed over an inner (e.g., bottom) surface of the airbridge 302 (e.g., by forming the dielectric layer on a sacrificial material, forming the airbridge on the dielectric layer, removing a portion of the dielectric layer in one or more areas away from the airbridge to provide access to the sacrificial material for release, and removing the sacrificial material to release the airbridge 302). In some implementations, a dielectric layer may be formed over an inner (e.g., bottom) surface of the airbridge 321 (e.g., by forming the dielectric layer on a sacrificial material, forming the airbridge on the dielectric layer, removing a portion of the dielectric layer in one or more areas away from the airbridge to provide access to the sacrificial material for release, and removing the sacrificial material to release the airbridge 321). In an implementation in which the airbridge is formed using an etch process, the removal of the portion of the dielectric layer in the one or more areas away from the airbridge may occur naturally as part of the etch process.

In the example of FIG. 3, the superconducting elements 312 of the Josephson junction 300 connect directly to the superconducting ground plane 306. For example, a removal process (e.g., an ion milling process) may be performed prior to formation of the superconducting elements to allow portions of the superconducting elements 312 to contact the ground plane layer 306. For example, by choosing the appropriate ion milling angle, the superconducting elements 312 can be deposited resulting in connection to the ground plane layer 306. In one or more other implementations, a bandage layer including one or more other superconducting features (e.g., as described hereinafter in connection with the conductive elements 401 of FIG. 4) may be provided to connect the superconducting elements 312 to the ground plane layer 306.

The flip-chip 3D architecture of the superconductor device 301 of FIG. 3 (e.g., in which the substrate 304 having the Josephson junction 300, the airbridge 302, the bond stops 318, the UBMs 326, and first portions of the bumps 316 is flipped and bonded to another substrate 320) is merely illustrative, and other implementations of a superconductor device formed using the disclosed surface treatment are contemplated. For example, FIG. 4 illustrates a cross-sectional side view of a portion of a superconductor device in accordance with one or more other implementations.

In the example of FIG. 4, the Josephson junction 300, the airbridge 302, and the ground plane layer 306 are formed on the substrate 304. In this example, a portion of the dielectric layer 310 is disposed between a portion of the superconducting elements 312 and the ground plane layer 306. In this example, the dielectric layer 310 may prevent direct contact between the superconducting elements 312 and the ground plane layer 306, and may also prevent contact between the non-superconducting material 314 and the substrate 304 (e.g., the dielectric layer 310 may extend under substantially the entire bottom surface of the superconducting elements of the Josephson junction 300). As shown, a pair of additional conductive features 401 (e.g., additional superconducting elements, which may be formed form the same or different superconducting materials from the material(s) that form the superconducting elements 312) may electrically couple the pair of superconducting elements 312 to the ground plane layer 306. As shown, a dielectric layer 404 may be formed over the Josephson junction 300 and the additional conductive features 401. For example, the surface treatment disclosed herein may be applied to remove native oxide layers from the superconducting elements 312, the additional conductive features 401, and the ground plane layer 306, and to deposit (e.g., without breaking vacuum following the removal), the dielectric layer 404 on the superconducting elements 312, the additional conductive features 401, and the ground plane layer 306.

In the example of FIG. 4, a dielectric layer 405 is disposed on a surface (e.g., an outer surface) of the airbridge 302. The dielectric layer 405 may be a portion of the dielectric layer 310 or a portion of the dielectric layer 404. As shown, a dielectric layer 402 may also be disposed on another surface (e.g., an opposing surface, such as an inner surface that faces, and is separated by an air gap from, the ground plane layer 306 and/or the substrate 304, which may include the dielectric layer 310 formed thereon) of the airbridge 302. The dielectric layer 402 may be a portion of the dielectric layer 310 or a portion of the dielectric layer 404. In the example of FIG. 4, one or both of the surfaces of the airbridge 302 on which the dielectric layers 402 and 404 are formed may be free of native oxide layers (e.g., due to a removal of native oxide layers during an application of the surface treatment disclosed herein). The dielectric layers 308, 310, 311, 402, and 404 may each be thin dielectric layers having a thickness (e.g., in a direction orthogonal to the surface of the substrate 304) of between one nanometer (nm) and three nm, or between one nm and five nm, less than five nm, less than three nm, or less than ten nm). The dielectric layers 308, 310, 311, 402, and 404 may each be formed from, as examples, alumina (e.g., Al₂O₃), aluminum nitride (AlN), silicon nitride (e.g., Si₃N₄), or magnesium oxide (MgO)

FIGS. 5A-5L illustrate various stages of fabrication of a superconductor device, using a fabrication process 501 that includes one or more applications of the surface treatment described herein. For example, the substrate 304 is shown in FIG. 5A. The substrate 304 may undergo a pre-metallization procedure, in which the substrate is cleaned and prepared for fabrication. For example, prior to the stage shown in FIG. 5A, a surface of the substrate 304, which may contain native oxides and surface contaminants, may be removed using, for example, a solvent treatment. For example, the substrate may be formed from a high resistivity silicon, and a cleaning process for the silicon may include thermal oxidation to a few hundred nanometers, followed by a buffered oxide etch to remove the top oxide. The buffered etch may be followed by acid and base treatments, to clean any surface contamination. However, this is merely illustrative, and substrates other than silicon, and/or other cleaning processes can also be used.

Following this cleaning process, the substrate 304 of FIG. 5A may then be ready for the surface treatment disclosed herein. For example, following the cleaning (e.g., following the buffered etch and acid and base treatments), the substrate 304 may (e.g., in a vacuum chamber) undergo a native oxide layer removal from the surface 500 thereof, and then a passivation of the surface 500 by deposition of a dielectric layer 502 as shown in FIG. 5B (e.g., in preparation for ground plane, junction formation, and/or other subsequent fabrication operations). For example, the native oxide layer removal may include an atomic layer etching (e.g., ALE) or other etching process that controllably (e.g., consistently and repeatably) removes thin layers of oxide (e.g., a native oxide layer 507 that forms on the surface 500 of the substrate 304 after the cleaning of the substrate, such as upon exposure of the cleaned substrate to air). For example, the deposition of the dielectric layer 310 may include an atomic layer deposition (e.g., ALD) process, or other deposition process suitable for depositing uniform and thin (e.g., less than a few nanometers) dielectric films.

By performing the surface treatment (e.g., the removal of the native oxide layer 507, and the deposition of the dielectric layer 502, such as by performing an ALE process following by an ALD process, without breaking vacuum between the ALE and ALD processes) on the substrate 304, superconducting circuit elements, such as the quantum circuit elements 210 of FIG. 2, including Josephson junctions, may be formed on top of a treated substrate, which provides targeting benefits, as discussed herein.

FIGS. 5C and 5D illustrate two different options for formation of the ground plane layer 306 on the treated substrate of FIG. 5B. In the example of FIG. 5C, a subtractive process (e.g., a subtractive process that is compatible with superconducting materials such as Al, Nb, Ta, TiN, etc.) is performed for the metal ground plane formation (e.g., by depositing a uniform superconductor film on the substrate under vacuum, and then patterning, using e-beam or photolithography followed by dry or wet etch, the uniform superconductor film to form the ground plane layer 306). In the example of FIG. 5D, an additive process (e.g., a liftoff process) is performed for metal ground plane formation (e.g., by depositing a uniform metal layer over a patterned photoresist layer, and removing portions of the uniform metal layer by removing the photoresist layer).

In either of the examples of FIGS. 5C and 5D, after the ground plane layer 306 is formed on the substrate 304, a removal (e.g., using ALE) of one or more native oxide layers from exposed portions of the substrate 304 and from the ground plane layer 306 may be performed, followed (e.g., without breaking vacuum) by deposition (e.g., using ALD) of the dielectric layer 310 on the exposed portions of the substrate 304 and the ground plane layer 306 from which the native oxide layer(s) have been removed. For example, although the one or more native oxide layers on the exposed portions of the substrate 304 and from the ground plane layer 306 not explicitly shown in FIGS. 5C and 5D (due to the removal thereof, prior to the dielectric deposition), the one or more native oxide layers may form on the ground plane layer and/or the substrate upon exposure of the substrate with the ground plane layer thereon to an ambient environment (e.g., including air).

In the example of FIG. 5C, during the patterning of the ground plane layer 306, there may be an over-etch into the substrate that would remove the treated substrate surface in these over-etched areas (e.g., in implementations in which the surface treatment was previously applied to the surface 500 of the substrate 304). Applying (e.g., re-applying) the surface engineering treatment after the etching process for the ground plane layer 306 circumvents this this treated surface removal, and allows execution of subsequent junctions and other component fabrication processes on the treated substrate surface even after etching processes for formation of the ground plane layer 306. In the example of FIG. 5D, the surface treatment may be applied after forming the ground plane layer 306 via the additive process.

After the ground plane layer 306 is formed and the surface treatment is applied, junctions, such as the Josephson junction 300, can be fabricated, as illustrated in FIG. 5E. For example, junction formation may include various processing operations (e.g., including double angle evaporation) to form the non-superconducting material 314, and to form the superconducting elements 312 separated by the non-superconducting material (e.g., and in contact with the ground plane layer 306 and/or the dielectric layer 310).

As shown in FIG. 5F, in one or more implementations, the surface treatment may be applied (e.g., again) following formation of the Josephson junction 300 (e.g., and following a subsequent bandage process) on the substrate 304. For example, one or more native oxide layers may be removed from the outer surfaces of the junction elements (e.g., the superconducting elements 312 and the non-superconducting material 314), the ground plane layer 306, and exposed portions (e.g., portions not covered by the ground plane layer 306) of the substrate 304. The dielectric layer 311 may be applied (e.g., without breaking vacuum following the oxide layer removal) over the Josephson junction 300, the ground plane layer 306, and exposed portions of the substrate 304. Performing the surface treatment after junction formation in this way may extend the benefits of surface treatment, combining removal of non-optimal dielectrics and encapsulation with fresh, well-controlled dielectric to the surface of junctions. Depending on the chemical selectivity of the oxide etch process, and/or whether the same metal is used for the junctions and the ground plane, the native oxide of the ground plane may also be stripped during the first portion (e.g., the oxide removal) of the surface treatment at this stage of fabrication.

In the example of FIGS. 5E and 5F, the junction formation is performed immediately after the surface treatment has been applied to the ground plane layer, and the surface treatment that deposits the dielectric layer 311 is then applied immediately after junction formation. However, the junction formation, and/or the surface treatment that is applied to the junction(s) may alternatively be applied at later stages of fabrication of the superconductor device 301, if desired.

FIGS. 5G-5L illustrate additional stages of the fabrication process 501 that may be performed in implementations in which the fabrication process 501 produces a flip-chip (e.g., 3D) superconductor device 301, as in the example of FIG. 3. For example, as shown in FIG. 5G, following the fabrication stage shown in FIG. 5E, one or more airbridges, such as the airbridge 302, may be formed on the substrate without the presence of the dielectric layer 404 over the junction(s) (e.g., Josephson junction 300). For example, forming the airbridge 302 may include depositing a sacrificial material over the dielectric layer 310, forming a superconducting material 400 for the airbridge on the sacrificial material, and removing the sacrificial material to leave an air gap under the airbridge 302.

As shown in FIG. 5H, bond stops 318 may be formed on the substrate 304 (e.g., over the dielectric layer 310). As shown in FIG. 5I, under-bump metallizations (UBMs) 326 may be formed on the ground plane layer 306 (e.g., by removing a portion of the dielectric layer 310 and depositing a metal on the ground plane layer 306 at the location of the removed dielectric layer 310). As shown in FIG. 5J, after formation of the UBMs 326, the surface treatment may be performed, resulting in the dielectric layer 404 over the Josephson junction 300, the ground plane layer 306, the UBMs 326, the airbridge 302, and the bond stops 318. For example, the dielectric layer 404 may be deposited after removal of one or more native oxide layer(s) of the junctions, the metal ground plane, the UBMs, and the exposed substrate (e.g., without breaking vacuum following the removal of the one or more native oxide layers). In this example, the dielectric layer 404 is deposited close to the end of wafer completion (e.g., in anticipation of the formation of low-melting point bumps, such as indium bumps). For example, as shown in FIG. 5K, bumps 316 (e.g., indium bumps) may be formed on the UBMs 326 (e.g., by removing a portion of the dielectric layer 404 and depositing bump material on the UBMs 326 at the location of the removed dielectric layer 404).

The fabrication operations illustrated by FIGS. 5G-5K account for the compatibility of the surface treatment for the various components (e.g., junctions, airbridges, ground planes, metallizations, resonators, etc.) on the wafer. In particular, processes that involve high temperatures, such as ALE and ALD, are not compatible with low-melting point elements such as indium and tin (150C and 232C, respectively) that can be utilized as bump features to bond opposing chips to each other for flip-chip 3D architectures. The example process of FIGS. 5G-5K fabricates components that do not involve such elements, including airbridges (FIG. 5G), bond stops (FIG. 5H), under bump metallizations (FIG. 5I), etc. and then carries out the surface engineering treatment as illustrated by FIG. 5J, before forming the bump layer (FIG. 5K). It is appreciated that the components do not need to be formed in the specific order shown in FIGS. 5G-5K. For example, UBM, bond stop, and airbridge fabrication operations can be permutated and/or omitted.

For 3D architectures as in the example of FIG. 3, a separate routing wafer that produces complementary chips can also be fabricated. The routing wafer may carry resonators (e.g., resonators 293) and routing lines in a superconducting ground plane layer that can be also impacted by lossy native oxides. In one or more implementations, the disclosed surface treatment can also be applied to the routing wafer to derive similar benefits to those described herein from applying the surface treatment to the substrate 304, the airbridge 302, and/or the ground plane layer 306. For example, a portion of a routing wafer that forms the substrate 320 is shown in FIG. 5L.

In order to form the device shown in FIG. 5L, pre-metallization operations (e.g., as described for the substrate 304 in connection with FIG. 5A) may also be performed on the substrate 320, and the subtractive or liftoff operations (e.g., described in connection with FIG. 5C or 5D for the ground plane layer 306) may be also performed to form the ground plane layer 322. The surface treatment may be performed prior to formation of the ground plane layer 322 (e.g., on the substrate 320) and/or after formation of the ground plane layer 322 (e.g., on the ground plane layer 322 and exposed portions of the substrate 320). For example, after formation of the ground plane layer 322 (e.g., in a subtractive or liftoff process), one or more native oxide layers may be removed from the ground plane layer 322 and exposed portions of the substrate 320, and the dielectric layer 324 may be deposited over the ground plane layer 322 and exposed portions of the substrate 320 having had the oxide layer(s) removed (e.g., without breaking vacuum between the removal of oxide layer(s) and deposition of the dielectric layer 324).

In the example of FIG. 5L, a routing device for the superconductor device is illustrated, and junction formation operations may be omitted for the substrate 320. One or more airbridges, such as the airbridge 321 may be formed on the substrate 320 (e.g., in contact with the ground plane layer 322), such as using the operations described herein in connection with the airbridge 302 in FIG. 5G), and under-bump metallizations 328 may be formed on the ground plane layer 322 (e.g., using the operations described herein in connection with the UBMs 326 in FIG. 5I). As indicated by FIG. 5L, bump material 515 (e.g., for bonding to bump material on the substrate 304 to form the bumps 316) may be formed on the UBMs 328. After dicing and flip-chip bonding (e.g., flipping the device shown in FIG. 5K and bonding the flipped device to the device shown in FIG. 5L), the resulting superconductor device 301 of FIG. 3 may be provided.

As discussed herein, the fabrication stages shown in FIGS. 5G-5L may be performed to fabricate the superconductor device 301 as in the example of FIG. 3. In other implementations in which the fabrication process 501 produces a planar (e.g., non-3D flip chip) superconductor device (as in the example of FIG. 4), following the fabrication stage shown in FIG. 5E, the airbridge 302 may be formed on the substrate 304. The conductive features 401 of FIG. 4 may also be formed in contact with the superconducting elements 312 and the ground plane layer 306. The surface treatment then may be applied to the Josephson junction 300, the airbridge 302, the ground plane layer 306, the conductive features 401, and the exposed portions of the substrate 304 following airbridge and/or conductive feature 401 formation (e.g., including a release of the airbridge 302 via removal of a sacrificial material on which the superconducting airbridge material is formed). For example, one or more native oxide layers may be removed from the outer surfaces of the Josephson junction 300, the airbridge 302, the ground plane layer 306, the conductive features 401, and the exposed portions of the substrate 304, and the dielectric layer 404 may be deposited, resulting in the superconductor device of FIG. 4.

In the implementation of FIG. 4 (e.g., and/or other implementation in which bump bonds are not present and/or the surface treatment remains within the thermal budget of bump material on the wafer), the surface treatment can also be performed at the end of line, at the die level. Performing the surface treatment at the die level may provide benefits, as the treated surfaces are not exposed subsequently to further processing before cryogenic cooling. An example of such a process includes performing the fabrication operations described in connection with FIGS. 5A-5G, followed by dicing and singulation. Singulated dies can then be processed individually, or in batches, using the surface treatment disclosed herein, resulting in encapsulation as shown in FIG. 4 for a die without bump bonds.

In one or more implementations, singulated dies may be processed using a surface treatment process that does not include deposition of a dielectric layer. For example, the device of FIG. 4 may be provided without the dielectric layer 404 and/or 405. In one or more implementations, singulated dies may be processed using a surface treatment process that includes a removal of one or residual contaminants resulting from the prior fabrication processes, such as a removal of one or more polymeric residues (e.g., photoresists or other fabrication resists). In one or more implementations, removal of the one or more polymeric residues may be performed using a cleaning process, such as an atomic layer etch (ALE) process. The cleaning process that removes the one or more polymeric residuals may be performed without entirely removing the native oxide layer in some implementations. It is also appreciated that a cleaning process that removes the one or more polymeric residuals may be performed at one or more prior stages of the process 501 (e.g., by cleaning the native oxide layer 507 on the substrate 304, cleaning the substrate 304, cleaning the ground plane layer 306, cleaning the surface(s) of the junction 300, cleaning the surface(s) of an airbridge 400, and/or cleaning any other surfaces and/or native oxide layers on those surfaces to remove polymeric residues during the fabrication process 301).

In one or more implementations, a cleaning process to remove polymeric residues may be performed without performing a separate native oxide layer removal, such as within a vacuum chamber and without breaking vacuum between the cleaning and the dielectric layer deposition. In one or more implementations, a cleaning process to remove polymeric residues may be performed in addition to the native oxide layer removal and the dielectric layer deposition of the surface treatment disclosed herein, such as within a vacuum chamber and without breaking vacuum between the native oxide removal, the cleaning, and/or the dielectric layer deposition.

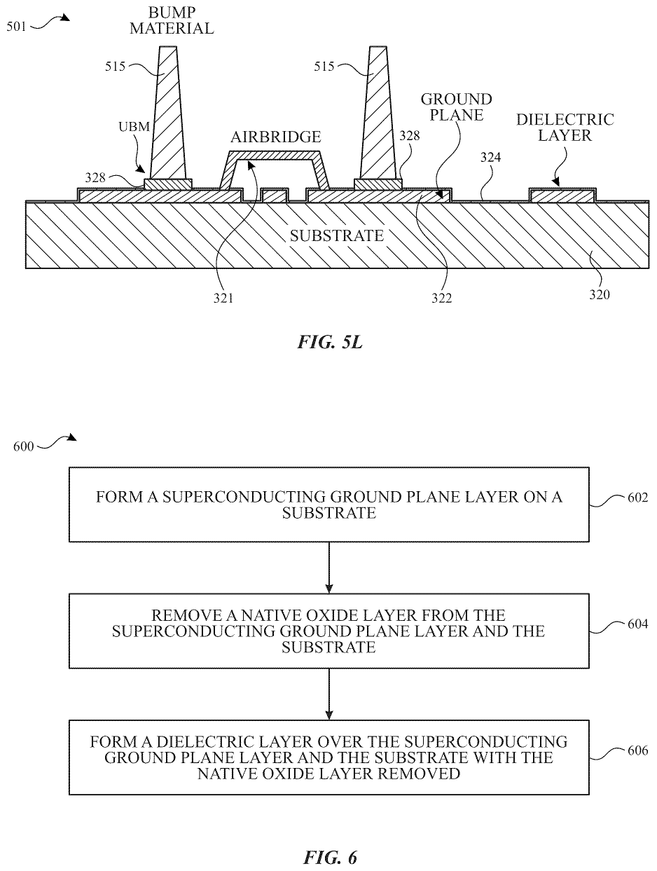

FIG. 6 illustrates a flow diagram of an exemplary process 600, in accordance with one or more embodiments of the subject technology. For explanatory purposes, the process 600 is primarily described herein with reference to FIGS. 1-5L. However, the process 600 is not limited to the items shown in FIGS. 1-5L, and one or more blocks (or operations) of the process 600 may be performed by one or more other components of other suitable devices. Further, for explanatory purposes, the blocks of the process 600 are described herein as occurring serially or linearly. However, multiple blocks of the process 600 may occur in parallel. In addition, the blocks of the process 600 need not be performed in the order shown and/or one or more blocks of the process 600 need not be performed and/or may be replaced by other operations.

At block 602, a superconducting ground plane layer (e.g., ground plane layer 306) may be formed on a substrate (e.g., substrate 304). As discussed herein, a superconducting ground plane layer may be formed on a substrate using a subtractive process (e.g., as in the example of FIG. 5C) or an additive (e.g., liftoff) process (e.g., as in the example of FIG. 5D).

At block 604, a native oxide layer may be removed from the superconducting ground plane layer and the substrate (e.g., from exposed portions of the substrate that are not covered by the superconducting ground plane layer). For example, the native oxide layer may form on the superconducting ground plane layer and/or the substrate when the substrate having the superconducting ground plane layer thereon is exposed to an ambient environment (e.g., air) after formation of the superconducting ground plane layer. This native oxide layer may be removed. In one or more implementations, removing the native oxide layer may include performing an atomic layer etch (ALE) process, or one or more other etching process that can uniformly and controllably remove thin (e.g., nanometer) oxide layers.

At block 606, a dielectric layer (e.g., dielectric layer 310) may be formed over the superconducting ground plane layer and the substrate having had the native oxide layer removed. For example, removing the native oxide layer and forming the dielectric layer (e.g., the surface treatment) may be performed within a vacuum (e.g., in a vacuum chamber), and without breaking the vacuum between removing the native oxide layer and forming the dielectric layer. The dielectric layer may be a thin dielectric layer having a thickness of between one nanometer and three nanometers, or less than five nanometers, in some implementations.

In one or more implementations, a superconducting circuit element (e.g., a Josephson junction, such as Josephson junction 300, another non-linear superconducting element, a resonator, an airbridge, or other superconducting circuit element) may be formed on the substrate, with a portion of the superconducting circuit element formed in contact with the dielectric layer (e.g., as discussed herein in connection with FIGS. 3, 4, and 5E). For example, the superconducting circuit element may be a Josephson junction, and forming the Josephson junction may include forming a pair of superconducting elements, such as superconducting elements 312, separated by a non-superconducting material, such as non-superconducting material 314.

In one or more implementations, the process 600 may also include removing another native oxide layer from the superconducting circuit element; and forming another dielectric layer (e.g., dielectric layer 311 of FIG. 5F, or dielectric layer 404 of FIG. 4 or FIG. 5J) over the superconducting circuit element.

In one or more implementations, the process 600 may also include, prior to forming the ground plane layer on the substrate at block 602: removing another native oxide layer from the substrate; and forming another dielectric layer (e.g., dielectric layer 502) on the substrate having had the native oxide layer removed. In one or more implementations, the process 600 may also include, prior to removing the other native oxide layer from the substrate, performing a pre-metallization process on the substrate (e.g., as described herein in connection with FIG. 5A).

In one or more implementations, the process 600 may also include forming, after forming the superconducting circuit element, an airbridge (e.g., airbridge 302) on the substrate; removing another native oxide layer from a surface of the airbridge; and forming another dielectric layer (e.g., dielectric layer 404) on the airbridge having had the other native oxide layer removed (e.g., as discussed herein in connection with FIGS. 3, 4, and/or 5J).

In one or more implementations, the substrate is a wafer substrate, and the process 600 may also include dicing the wafer substrate; removing another native oxide layer from a die formed from the dicing; and forming another dielectric layer (e.g., dielectric layer 404 and/or 405 of FIG. 4) over the die having had the other native oxide layer removed.

In various implementations, the process 600 may include any or all of the fabrication operations described herein in connection with FIGS. 3-5L. The process 600 may also include wire bonding, packaging, and cooldown of the superconductor device to cryogenic temperatures to perform as superconducting circuits (e.g., superconducting quantum circuits, such as in a quantum processor 202).

Performing the surface treatment disclosed herein (e.g., native oxide removal and dielectric deposition without breaking vacuum) at various stages in the fabrication of superconductor devices, such as the superconductor device 301 of FIG. 3 or FIG. 4 (or the device shown in FIG. 5F), may provide various benefits. For example, the operating regime for superconducting circuits may be improved. Measuring the room temperature resistance and Ej is a technique for estimating the transmon frequency without performing costly cryogenic measurements. Room temperature resistance measurements of superconductor devices produced as described herein show that, when junctions are deposited (e.g., as described in connection with FIG. 5C or 5D) on substrates treated with the surface treatment (e.g., as described in connection with FIG. 5B), wafer-to-wafer reproducibility was significantly improved. The process control and targeting achieved with this implementation of the surface treatment is 1.40+/−3.93% (1σ), in contrast with a deviation of 13.06+/−18.78% (1σ) for substrates that do not undergo the disclosed surface treatment.

As another example, aging of a wafer components during fabrication may be reduced. After junction formation, downstream processing through wet chemistry and thermal events can cause the junction resistance to drift, which has been termed “aging”. When junctions are deposited (e.g., as described in connection with FIG. 5C or 5D) on substrates treated with the surface treatment (e.g., as described in connection with FIG. 5B), the junctions tend to age less. For example, resistance changes due to aging between junction formation and wafer completion for a process without surface treatment of the substrate can be as high as 11.8+/−1.5% (1σ). When junctions are deposited (e.g., as described in connection with FIG. 5C or 5D) on substrates treated with the surface treatment (e.g., as described in connection with FIG. 5B), surface aging is reduced to 5.4+/−0.8% (1σ). This reduction in aging results in a more predictable junction resistance, which helps with frequency targeting. Overall frequency targeting, in part, determines the performance of superconducting devices in ways such as minimizing frequency collisions and preserving the coherence times of prepared qubit states (thus quantum information) encoded onto superconducting circuits.

As another example, within-wafer resistance uniformity may be improved. For example, for an encapsulated junction as shown in FIG. 5F, a 2× reduction in the within-wafer resistance spread at room temperature is observed, reduced from 6.9% 1σ (e.g., for a junction without the surface treatment applied) to as low as 2.9% 1σ (e.g., for the junction shown in FIG. 5F). The treated junctions also exhibit reduced aging induced by post-junction fabrication processes, which assists with targeting as already described. To further provide better targeting, process knobs such as substrate temperature, addition of oxygen or ozone reactant before or after ALE, followed by ALD dielectric encapsulation can be adjusted in order to manipulate resistance values to their desired targets.

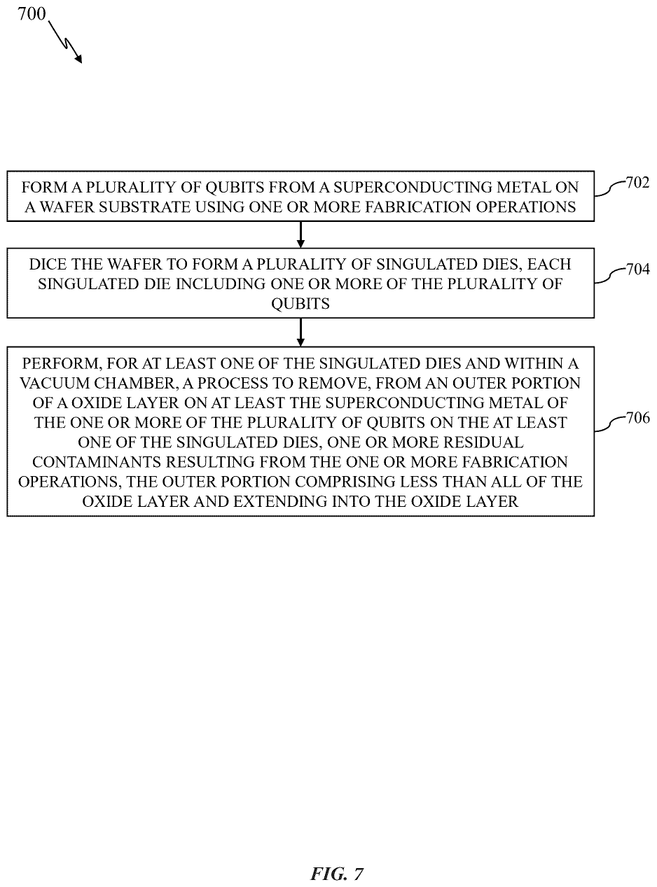

As another example, cryogenic coherence times may be increased. For example, improved cryogenic performance for superconducting devices is observed when the disclosed surface treatment is applied at the end of line, as described in connection with FIG. 4. Namely, a significant increase in median T₁ and 72 times is observed, from 15% up to 150% and 75% up to 175%, for T₁ and T₂ respectively. These improvements in T₁ and T₂ are associated with an overall 40% to 170% increase in median transmon quality (Q) due to the reduced surface losses attributed to better dielectric quality and/or reduced polymeric residues. In one or more implementations, the surface treatment that is performed at the end of the line (e.g., to improve qubit coherence times) may include native oxide removal and/or polymeric residue removal, with or without applying another dielectric layer at this stage (e.g., as discussed hereinafter in connection with FIG. 7).

As another example, resonator performance may be improved. Although the surface treatment process disclosed herein is described as being applied to bare substrates, ground plane layers, junctions, and airbridges in various examples, the subject technology is not limited to these components. Individual resonator quality factors can be measured and used as a proxy to estimate microwave losses in superconducting circuits. Applying the disclosed surface treatment to one or more resonators on a substrate also provides a boost to the cryogenic performance of the resonators. For example, a reduction of half of the loss tangent is observed for aluminum resonators that have been treated according to the stage shown in FIG. 3.

FIG. 7 illustrates a flow diagram of an exemplary process 700, in accordance with one or more embodiments of the subject technology. For explanatory purposes, the process 700 is primarily described herein with reference to FIGS. 1-5L. However, the process 700 is not limited to the items shown in FIGS. 1-5L, and one or more blocks (or operations) of the process 700 may be performed by one or more other components of other suitable devices. Further, for explanatory purposes, the blocks of the process 700 are described herein as occurring serially or linearly. However, multiple blocks of the process 700 may occur in parallel. In addition, the blocks of the process 700 need not be performed in the order shown and/or one or more blocks of the process 700 need not be performed and/or may be replaced by other operations.

At block 702, a plurality of qubits (e.g., qubits 210, such as qubits including Josephson junctions 300) may be formed from a superconducting metal (e.g., ground plane layer 306) on a wafer substrate (e.g., substrate 304) using one or more fabrication operation (e.g., including one or more of the fabrication operations illustrated in FIGS. 5A-5L).

At block 704, the wafer may be diced to form a plurality of singulated dies (e.g., a singulated die corresponding to the superconducting device 301), each singulated die including one or more of the plurality of qubits. For example, the one or more of the plurality of qubits may include one or more superconducting transmons.

At block 706, for at least one of the singulated dies and within a vacuum chamber, a process (e.g., a cleaning process) may be performed to remove, from an outer portion of an oxide layer on at least the superconducting metal of the one or more of the plurality of qubits on the at least one of the singulated dies, one or more residual contaminants resulting from the one or more fabrication operations. The outer portion may include less than all of the oxide layer and may extend into the oxide layer. For example, performing the process may increase a coherence time of the one or more of the plurality of qubits on the at least one of the singulated dies (e.g., relative to a coherence time of the one or more of the plurality of qubits after singulation of the wafer substrate to form the singulated die and prior to removal of the one or more residual contaminants). For example, the coherence times may be improved from 15% up to 150% and 75% up to 175%, for T₁ and T₂ respectively.

In one or more implementations, the process 700 may also include forming, following performing the process, a dielectric layer (e.g., dielectric layer 311, 404, and/or 405) over the one or more of the plurality of qubits on the at least one of the singulated dies. In one or more implementations, performing the process and forming the dielectric layer may include performing the process and forming the dielectric layer within a vacuum chamber and without breaking vacuum between performing the process and forming the dielectric layer.

In one or more implementations, the process 700 may also include cryogenically cooling, after performing the process, the at least one of the singulated dies; and performing a quantum computation using the cryogenically cooled at least one of the singulated dies. In one or more implementations, the oxide layer may be a native oxide layer, the process may include an atomic layer etch, and the outer portion of the native oxide layer may extend less than five nanometers into the native oxide layer.

In one or more implementations, a superconductor device formed at least in part from the process 700 may include a singulated die; and one or more qubits formed from a superconducting metal on the singulated die. One or more residual contaminants resulting from one or more fabrication operations for forming the superconducting metal may have been removed from an outer portion of an oxide layer on at least the superconducting metal of the one or more qubits, the outer portion including less than all of the oxide layer and extending into the oxide layer.

In one or more implementations, a quantum computing formed at least in part from the process 700 may include at least one quantum processor that includes a singulated die; and one or more qubits formed from a superconducting metal on the singulated die. One or more residual contaminants resulting from one or more fabrication operations for forming the superconducting metal may have been removed from an outer portion of an oxide layer on at least the superconducting metal of the one or more qubits, the outer portion including less than all of the oxide layer and extending into the oxide layer.

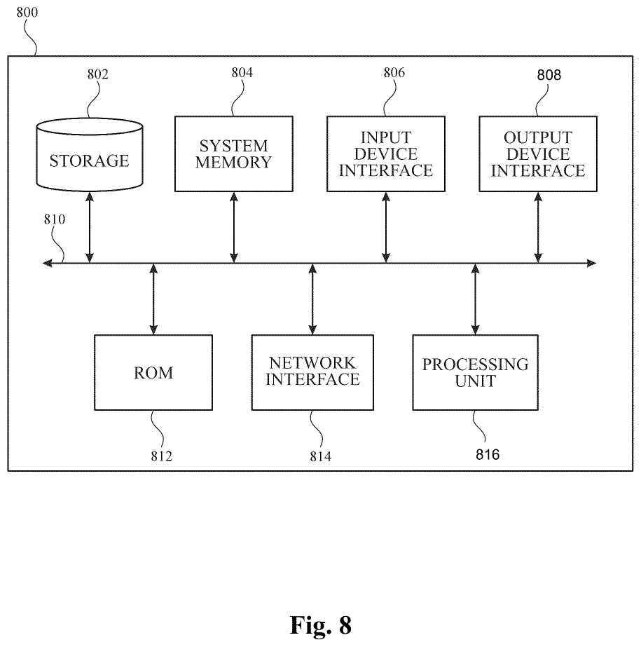

FIG. 8 illustrates an example electronic system 800 in which aspects of the present disclosure may be implemented, in accordance with one or more embodiments of the subject technology. The electronic system 800 may be, and/or may be a part of, a computing device (e.g., client devices 102, server(s) 106, and/or quantum computing systems 108). The electronic system 800 may include various types of computer-readable media and interfaces for various other types of computer-readable media. The electronic system 800 may include a bus 810, a storage device 802, a system memory 804, an input device interface 806, an output device interface 808, a ROM 812, a network interface 814, and a processing unit 816, or subsets and variations thereof. Not all depicted components may be used in all embodiments, however, and one or more embodiments may include additional or different components than those shown in the figure. Variations in the arrangement and type of the components may be made without departing from the spirit or scope of the claims as set forth herein. Additional components, different components, or fewer components may be provided.

Network interface 814 may be configured to allow data to be exchanged between the electronic system 800 and devices attached to a network or networks (e.g., network 104), such as other computer systems or devices. In various embodiments, network interface 814 may support communication via any suitable wired or wireless general data networks, such as types of Ethernet networks, for example. Additionally, network interface 814 may support communication via telecommunications/telephony networks, such as analog voice networks or digital fiber communications networks, via storage area networks such as Fiber Channel SANs (storage area networks) or via any other suitable type of network and/or protocol.

The bus 810 collectively represents all system, peripheral, and chipset buses that communicatively connect the numerous internal devices of the electronic system 800. In one or more embodiments, the bus 810 communicatively connects the processing unit 816 with the other components of the electronic system 800 (e.g., the ROM 812, the system memory 804, and the persistent storage device 802). From various memory units, the processing unit 816 retrieves instructions to execute and data to process in order to execute the operations of the subject disclosure. The processing unit 816 may be a controller and/or a single- or multi-core processor or processors in various embodiments.

The ROM 812 may store static data and instructions that are needed by the one or more processing unit(s) 816 and other modules of the electronic system 800. The storage device 802, on the other hand, may be a read-and-write memory device. The storage device 802 may be a non-volatile memory unit that stores instructions and data (e.g., static and dynamic instructions and data) even when the electronic system 800 is off. Data may include one or more long-term data stores (e.g., databases). In one or more embodiments, a mass-storage device (such as a magnetic or optical disk and its corresponding disk drive) may be used as the storage device 802. In one or more embodiments, a removable storage device (such as a flash drive, and its corresponding disk drive) may be used as the storage device 802. Generally speaking, a computer-accessible medium may include non-transitory storage media or memory media, such as magnetic or optical media.

Like the storage device 802, the system memory 804 may be a read-and-write memory device. However, unlike the storage device 802, the system memory 804 may be a volatile read-and-write memory, such as random-access memory. The system memory 804 may store any of the instructions and data that one or more processing unit 816 may need at runtime to perform operations. Data may include one or more short-term data stores (e.g., caches and buffers). In one or more embodiments, the processes of the subject disclosure are stored in the system memory 804 and/or the storage device 802. From these various memory units, the one or more processing unit 816 retrieves instructions to execute and data to process in order to execute the processes of one or more embodiments, discussed below.

Embodiments within the scope of the present disclosure may be partially or entirely realized using a tangible computer-readable storage medium (or multiple tangible computer-readable storage media of one or more types) encoding one or more instructions. The tangible computer-readable storage medium also may be non-transitory in nature.

The computer-readable storage medium may be any storage medium that may be read, written, or otherwise accessed by a general-purpose or special-purpose computing device, including any processing electronics and/or processing circuitry capable of executing instructions. For example, without limitation, the computer-readable medium may include any transitory semiconductor memory (e.g., the system memory 804), such as RAM, DRAM, SRAM, T-RAM, Z-RAM, and TTRAM. The computer-readable medium also may include any non-transitory semiconductor memory (e.g., the storage device 802), such as ROM, SSD, PROM, EPROM, EEPROM, NVRAM, flash, nvSRAM, FeRAM, FeTRAM, MRAM, PRAM, CBRAM, SONOS, RRAM, NRAM, racetrack memory, FJG, and Millipede memory.

Further, the computer-readable storage medium may include any non-semiconductor memory, such as optical disk storage, magnetic disk storage, magnetic tape, other magnetic storage devices, or any other medium capable of storing one or more instructions. In one or more embodiments, the tangible computer-readable storage medium may be directly coupled to a computing device, while in other embodiments, the tangible computer-readable storage medium may be indirectly coupled to a computing device, e.g., via one or more wired connections, one or more wireless connections, or any combination thereof.

Instructions may be directly executable or may be used to develop executable instructions. For example, instructions may be realized as executable or non-executable machine code or as instructions in a high-level language that may be compiled to produce executable or non-executable machine code. Further, instructions also may be realized as or may include data. Computer-executable instructions also may be organized in any format, including routines, subroutines, programs, data structures, objects, modules, applications, applets, functions, etc. As recognized by those of skill in the art, details including, but not limited to, the number, structure, sequence, and organization of instructions may vary significantly without varying the underlying logic, function, processing, and output.

While the above discussion primarily refers to microprocessors or multi-core processors that execute software, one or more embodiments are performed by one or more integrated circuits, such as ASICs or FPGAs. In one or more embodiments, such integrated circuits execute instructions that are stored on the circuit itself.

The bus 810 also connects to the input device interface 806 and output device interface 808. The input device interface 806 enables the system to receive inputs. For example, the input device interface 806 allows a user to communicate information and select commands on the electronic system 800. The input device interface 806 may be used with input devices such as keyboards, mice, dials, switches, sliders, and other interfaces (physical or virtual) for a user to supply information to the electronic system 800. The output device interface 808 may be used with output devices such as displays, speakers, and other interfaces (physical or virtual) for the computing electronic system 800 to provide information. One or more embodiments may include devices that function as both input and output devices, such as a touchscreen.

The bus 810 also couples the electronic system 800 to one or more networks and/or to one or more network nodes through the network interface 814. The network interface 814 may include one or more interfaces that allow the electronic system 800 to be a part of a network of computers (e.g., a local area network (LAN), a wide area network (WAN), or a network of networks (the Internet)). For example, the network interface 814 may include a network interface card (NIC).

A network set up by an entity, such as a company or a public sector organization, to provide one or more web services (such as various types of cloud-based computing or storage) accessible via the Internet and/or other networks to a distributed set of clients may be termed a provider network. Such a provider network may include numerous data centers hosting various resource pools, such as collections of physical and/or virtualized computer servers, storage devices, networking equipment and the like, needed to implement and distribute the infrastructure and web services offered by the provider network. The resources may in some embodiments be offered to clients in various units related to the web service, such as an amount of storage capacity for storage, processing capability for processing, as instances, as sets of related services and the like. A virtual computing instance may, for example, comprise one or more servers with a specified computational capacity (which may be specified by indicating the type and number of CPUs, the main memory size and so on) and a specified software stack (e.g., a particular version of an operating system, which may in turn run on top of a hypervisor).

A compute node, which may be referred to also as a computing node, may be implemented on a wide variety of computing environments, such as commodity-hardware computers, virtual machines, web services, computing clusters and computing appliances. Any of these computing devices or environments may, for convenience, be described as compute nodes.

A number of different types of computing devices may be used singly or in combination to implement the resources of the provider network in different embodiments, for example computer servers, storage devices, network devices and the like. In some embodiments a client or user may be provided direct access to a resource instance, e.g., by giving a user an administrator login and password. In other embodiments the provider network operator may allow clients to specify execution requirements for specified client applications and schedule execution of the applications on behalf of the client on execution platforms (such as application server instances, Java™ virtual machines (JVMs), general-purpose or special-purpose operating systems, platforms that support various interpreted or compiled programming languages such as Ruby, Perl, Python, C, C++ and the like or high-performance computing platforms) suitable for the applications, without, for example, requiring the client to access an instance or an execution platform directly. A given execution platform may utilize one or more resource instances in some embodiments; in other embodiments, multiple execution platforms may be mapped to a single resource instance.

In many environments, operators of provider networks that implement different types of virtualized computing, storage and/or other network-accessible functionality may allow customers to reserve or purchase access to resources in various resource acquisition modes. The computing resource provider may provide facilities for customers to select and launch the desired computing resources, deploy application components to the computing resources and maintain an application executing in the environment. In addition, the computing resource provider may provide further facilities for the customer to quickly and easily scale up or scale down the numbers and types of resources allocated to the application, either manually or through automatic scaling, as demand for or capacity requirements of the application change. The computing resources provided by the computing resource provider may be made available in discrete units, which may be referred to as instances. An instance may represent a physical server hardware platform, a virtual machine instance executing on a server or some combination of the two. Various types and configurations of instances may be made available, including different sizes of resources executing different operating systems (OS) and/or hypervisors, and with various installed software applications, runtimes, and the like. Instances may further be available in specific availability zones, representing a logical region, a fault tolerant region, a data center or other geographic location of the underlying computing hardware, for example. Instances may be copied within an availability zone or across availability zones to improve the redundancy of the instance, and instances may be migrated within a particular availability zone or across availability zones. As one example, the latency for client communications with a particular server in an availability zone may be less than the latency for client communications with a different server. As such, an instance may be migrated from the higher latency server to the lower latency server to improve the overall client experience.

In some embodiments the provider network may be organized into a plurality of geographical regions, and each region may include one or more availability zones. An availability zone (which may also be referred to as an availability container) in turn may comprise one or more distinct locations or data centers, configured in such a way that the resources in a given availability zone may be isolated or insulated from failures in other availability zones. That is, a failure in one availability zone may not be expected to result in a failure in any other availability zone. Thus, the availability container of a resource instance is intended to be independent of the availability container of a resource instance in a different availability zone. Clients may be able to protect their applications from failures at a single location by launching multiple application instances in respective availability zones. At the same time, in some embodiments inexpensive and low latency network connectivity may be provided between resource instances that reside within the same geographical region (and network transmissions between resources of the same availability zone may be even faster).

As set forth above, content may be provided by a content provider to one or more clients. The term content, as used herein, refers to any presentable information, and the term content item, as used herein, refers to any collection of any such presentable information. A content provider may, for example, provide one or more content providing services for providing content to clients. The content providing services may reside on one or more servers. The content providing services may be scalable to meet the demands of one or more customers and may increase or decrease in capability based on the number and type of incoming client requests. Portions of content providing services may also be migrated to be placed in positions of reduced latency with requesting clients. For example, the content provider may determine an “edge” of a system or network associated with content providing services that is physically and/or logically closest to a particular client. The content provider may then, for example, “spin-up,” migrate resources or otherwise employ components associated with the determined edge for interacting with the particular client. Such an edge determination process may, in some cases, provide an efficient technique for identifying and employing components that are well suited to interact with a particular client, and may, in some embodiments, reduce the latency for communications between a content provider and one or more clients.

As used in this specification and any claims of this application, the terms “base station,” “receiver,” “computer,” “server,” “processor,” and “memory” all refer to electronic or other technological devices. These terms exclude people or groups of people. For the purposes of the specification, the terms “display” or “displaying” means displaying on an electronic device.

The predicate words “configured to,” “operable to,” and “programmed to” do not imply any particular tangible or intangible modification of a subject but, rather, are intended to be used interchangeably. In one or more embodiments, a processor configured to monitor and control an operation or a component may also mean the processor being programmed to monitor and control the operation or the processor being operable to monitor and control the operation. Likewise, a processor configured to execute code may be construed as a processor programmed to execute code or operable to execute code.

Phrases such as an aspect, the aspect, another aspect, some aspects, one or more aspects, an implementation, the implementation, another implementation, some embodiments, one or more embodiments, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations or one or more configurations. A disclosure relating to such phrase(s) may provide one or more examples. A phrase such as an aspect or some aspects may refer to one or more aspects and vice versa, which applies similarly to other foregoing phrases.

The word “exemplary” is used herein to mean “serving as an example, instance, or illustration.” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the phrase “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public, regardless of whether such disclosure is explicitly recited in the claims.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language claims, wherein reference to an element in the singular is not intended to mean “one and only one” unless specifically so stated, but rather “one or more.” Unless specifically stated otherwise, the term “some” refers to one or more. Headings and subheadings, if any, are used for convenience only and do not limit the subject disclosure.

What is claimed is:

1. A method, comprising:
forming a superconducting ground plane layer on a substrate;
removing a first native oxide layer from the superconducting ground plane layer and the substrate; and
forming a first dielectric layer over the superconducting ground plane layer and the substrate having had the native oxide layer removed.

2. The method of claim 1, further comprising forming a superconducting circuit element on the substrate, with a portion of the superconducting circuit element formed in contact with the first dielectric layer.

3. The method of claim 2, wherein removing the first native oxide layer and forming the first dielectric layer are performed within a vacuum, and without breaking the vacuum between removing the first native oxide layer and forming the first dielectric layer.

4. The method of claim 2, further comprising:
removing a second native oxide layer from the superconducting circuit element; and
forming a second dielectric layer over the superconducting circuit element.

5. The method of claim 2, further comprising, prior to forming the superconducting ground plane layer on the substrate:
performing a pre-metallization process on the substrate;
removing a second native oxide layer from the substrate;
forming a second dielectric layer on the substrate having had the native oxide layer removed.

6. The method of claim 2, further comprising:
forming, after forming the superconducting circuit element, an airbridge on the substrate;
removing a second native oxide layer from a surface of the airbridge; and
forming a second dielectric layer on the airbridge having had the other native oxide layer removed.

7. The method of claim 2, wherein the substrate comprises a wafer substrate, and wherein the method further comprises:
dicing the wafer substrate; and
performing a process to remove one or more polymeric residues from (i) a die formed from the dicing or (ii) the wafer substrate immediately before the dicing.

8. The method of claim 7, further comprising removing a second native oxide layer from the die formed from the dicing.

9. The method of claim 7, further comprising:
forming a second dielectric layer over the die having had the one or more polymeric residuals removed.

10. A superconductor device, comprising:
a substrate;
a superconducting circuit element on the substrate; and
a dielectric layer interposed between a portion of the superconducting circuit element and the substrate.

11. The superconductor device of claim 10, wherein the superconductor device is free of native oxide layers between the substrate and the superconducting circuit element.

12. The superconductor device of claim 10, wherein the superconducting circuit element comprises a Josephson junction, and wherein the portion of the superconducting circuit element comprises a non-superconducting material of the Josephson junction that is disposed between a pair of superconducting elements of the Josephson junction.

13. The superconductor device of claim 10, wherein the portion of the Josephson junction further comprises a portion of at least one of the pair of superconducting elements.

14. The superconductor device of claim 10, further comprising a ground plane layer on the substrate, wherein the dielectric layer extends over the ground plane layer, wherein a portion of each of the pair of superconducting elements is in contact with the ground plane layer, and wherein the ground plane layer is free of native oxide layers between the ground plane layer and the dielectric layer.

15. The superconductor device of claim 14, further comprising a pair of additional conductive features that electrically couple the pair of superconducting elements to the ground plane layer.

16. The superconductor device of claim 15, further comprising:
an airbridge on the substrate, wherein the airbridge comprises a portion of the dielectric layer on a first surface thereof; and
an additional dielectric layer formed over the Josephson junction, wherein a portion of the additional dielectric layer is formed on a second surface of the airbridge.

17. The superconductor device of claim 14, further comprising an additional dielectric layer disposed between the ground plane layer and the substrate.

18. The superconductor device of claim 10, further comprising an additional dielectric layer formed over the superconducting circuit element.

19. The superconductor device of claim 10, wherein the superconducting circuit element comprises a resonator, wherein the resonator is free of native oxide layers thereon, and wherein a portion of another dielectric layer extends over at least a portion of the resonator.

20. A quantum computer, comprising:
at least one quantum processor, comprising:
a substrate;
a superconducting circuit element on the substrate; and
a dielectric layer interposed between a portion of the superconducting circuit element and the substrate.
